(19) United States
(12) Patent Application Publication
(10) Pub. No.: US 2023/0162254 A1
(43) Pub. Date: May 25, 2023

(54) PRODUCT INFORMATION VISUALIZATION PROCESSING METHOD AND APPARATUS, AND COMPUTER DEVICE

(71) Applicant: SHENZHEN UNIVERSITY, Shenzhen, Guangdong (CN)

(72) Inventors: Ruizhen HU, Shenzhen (CN); Hui HUANG, Shenzhen (CN); Bin CHEN, Shenzhen (CN); Juzhan XU, Shenzhen (CN)

(21) Appl. No.: 17/997,491

(22) PCT Filed: Aug. 26, 2020
(86) PCT No.: PCT/CN2020/111320

§ 371 Date: Oct. 28, 2022

(30) Foreign Application Priority Data
Aug. 24, 2020 (CN) 202010856845.6

(51) Int. Cl. G06Q 30/0601; G06Q 30/0282

(52) U.S. Cl. CPC G06Q 30/0627; G06Q 30/0282

(57) ABSTRACT

A product information visualization processing method, including: acquiring product information; extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions.

### CROSS-REFERENCES TO RELATED APPLICATIONS

This application is a National Stage of PCT Patent Application No. PCT/CN2020/111320, entitled “PRODUCT INFORMATION VISUALIZATION PROCESSING METHOD AND APPARATUS, AND COMPUTER DEVICE”, filed on Aug. 26, 2020, which claims priority to Chinese Patent Application No. 2020108568456, entitled “PRODUCT INFORMATION VISUALIZATION PROCESSING METHOD AND APPARATUS, AND COMPUTER DEVICE” and filed with the China Patent Office on Aug. 24, 2020, the entire contents of which are incorporated herein by reference.

### TECHNICAL FIELD

The present disclosure relates to the field of computer technologies, and in particular, to a product information visualization processing method and apparatus, a computer device, and a storage medium.

### BACKGROUND

With the development of a computer technology and the advent of the 5G era, a variety of product information shows a massive growth pattern. In a cloud computing network, big data is a foundation and core technology of cloud computing. The big data includes a large number of high-dimensional data. Visualization processing on the high-dimensional data can help to grasp deep information contained in complex and changeable product information more quickly and accurately.

However, the current human cognitive ability has certain limitations. In a variety of conventional product information processing manners, it is impossible to perform effective visualization difference evaluation on information of multiple dimensions of different categories of products, for example, how to perform effective visualization difference evaluation on attribute information of multiple dimensions of different categories of vehicles. That is, users cannot be provided with a product multi-dimensional information visual structure difference from an intuitive global perspective. Therefore, how to effectively visualize multi-dimensional data included in product information has become an urgent main problem to be solved at present.

### SUMMARY

According to various embodiments of the present disclosure, a product information visualization processing method and apparatus, a computer device, and a storage medium are provided.

A product information visualization processing method, including:

acquiring product information; extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions.

A product information visualization processing apparatus, including:

an acquisition module configured to acquire product information; an extraction module configured to extract an attribute data set of multiple dimensions corresponding to the product information; and an identification module configured to input the attribute data set of the multiple dimensions into a pre-trained sorting model, and identify the attribute data set of each dimension by using the sorting model until sorting results corresponding to the multiple dimensions are outputted according to a preset number of attribute dimensions.

A computer device, including a memory and one or more processors, the memory storing computer-readable instructions, the computer-readable instructions, when executed by the one or more processors, causing the one or more processors to perform the following steps: acquiring product information;

extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions.

One or more computer storage media storing computer-readable instructions, the computer-readable instructions, when executed by one or more processors, causing the one or more processors to perform the following steps: acquiring product information;

extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions.

Details of one or more embodiments of the present disclosure are set forth in the following accompanying drawings and descriptions. Other features and advantages of the present disclosure will become obvious with reference to the specification, the accompanying drawings, and the claims.

### BRIEF DESCRIPTION OF THE DRAWINGS

In order to more clearly illustrate the technical solutions in embodiments of the present disclosure, the accompanying drawings used in the description of the embodiments will be briefly introduced below. It is apparent that the accompanying drawings in the following description are only some embodiments of the present disclosure, and other drawings can be obtained by those of ordinary skill in the art from the provided drawings without creative efforts.

FIG. 1 is a diagram of an application environment of a product information visualization processing method according to an embodiment.

FIG. 2 is a schematic flowchart of the product information visualization processing method according to an embodiment.

FIG. 3A is a schematic flowchart of a step of identifying an attribute data set of each dimension by using a sorting model according to an embodiment.

FIG. 3B is a schematic diagram of a network structure of the sorting model according to an embodiment.

FIG. 4 is a schematic flowchart of a step of training the sorting model according to an embodiment.

FIG. 5 is a schematic flowchart of the step of training the sorting model according to another embodiment.

FIG. 6A is a schematic flowchart of a step of training a distance prediction model according to an embodiment.

FIG. 6B is a schematic diagram of a network structure of the distance prediction model according to an embodiment.

FIG. 7 is a structural block diagram of a product information visualization processing apparatus according to an embodiment.

FIG. 8 is a diagram of an internal structure of a computer device according to an embodiment.

### DETAILED DESCRIPTION OF THE EMBODIMENTS

In order to make the technical solutions and advantages of the present disclosure more clearly understood, the present disclosure is described in further detail below with reference to the accompanying drawings and embodiments. It is to be understood that specific embodiments described herein are intended only to interpret the present disclosure and not intended to limit the present disclosure.

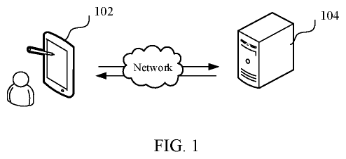

A product information visualization processing method according to an embodiment of the present disclosure may be applied to an application environment shown in FIG. 1. A terminal 102 communicates with a server 104 over a network. The terminal 102 sends a product information acquisition request to the server 104. According to the received product information acquisition request, the server 104 queries corresponding product information of multiple dimensions and returns corresponding sorting results to the terminal 102. The server 104 acquires product information. The server 104 extracts an attribute data set of multiple dimensions corresponding to the product information. The server 104 inputs the attribute data set of the multiple dimensions into a pre-trained sorting model. The server 104 identifies the attribute data set of each dimension by using the sorting model until sorting results corresponding to the multiple dimensions are outputted according to a preset number of attribute dimensions. The terminal 102 may be, but is not limited to, a variety of personal computers, laptop computers, smart phones, tablet computers, and portable wearable devices. The server 104 may be implemented as a standalone server or as a server cluster formed by a plurality of servers.

The following embodiments are described with an example in which the product information visualization processing method is applied to the server in FIG. 1. However, it is to be noted that the method is not limited to the above server in practical applications.

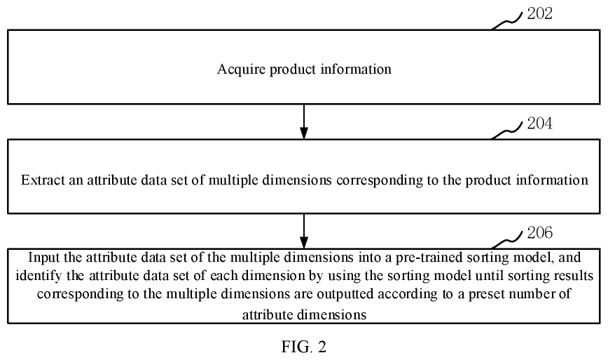

FIG. 2 shows a flowchart of a product information visualization processing method according to an embodiment. The method specifically includes the following steps.

In step 202, product information is acquired.

The server may receive product information query instructions sent by different terminals. The product information query instructions may be from users, staff, or the like. The server may receive the information query instructions in different manners in different scenarios. For example, the server may receive the product information query instructions by detecting gestures of the users or staff. The server may also receive the product information query instructions by detecting voice instructions of the users or staff. Specifically, when the server detects the product information query instructions sent by the users or staff, the server may acquire corresponding product information from a database according to the received product information query instructions. The product information refers to product-related messages, information, data, and the like. A product is anything that is offered to the market as a commodity to satisfy a need, including tangible goods, intangible services, organizations, ideas or a combination thereof. For example, the product information may include various types of product information, such as clothing, food, and vehicles. For different product information, the server cluster may lock different types of product resource information more specifically according to the product information query instructions.

In step 204, an attribute data set of multiple dimensions corresponding to the product information is extracted.

After the server acquires the product information, the server extracts an attribute data set of multiple dimensions corresponding to the product information. The attribute data set refers to a set of attribute data of multiple dimensions corresponding to a product, namely, a set of product attribute data. The product attribute data may include performance data of the product, such as strength, hardness, and security. For example, when product information in a product information query instruction sent by a user is Vehicle, after the server acquires various types of vehicle information, the server extracts an attribute data set of multiple dimensions corresponding to the various types of vehicle information, for example, vehicle performance data. The vehicle performance data may include performance data of multiple dimensions, such as power performance, fuel economy, braking performance, handling stability, riding comfort, and emission pollution and noise. A performance data set corresponding to each dimension may include a plurality of pieces of data. For example, a performance data set of the power performance dimension of the vehicle may include the following three key indexes: (1) a maximum speed parameter of the vehicle; (2) an acceleration capability parameter of the vehicle; and (3) gradeability of the vehicle.

In step 206, the attribute data set of the multiple dimensions is inputted into a pre-trained sorting model, and the attribute data set of each dimension is identified by using the sorting model until sorting results corresponding to the multiple dimensions are outputted according to a preset number of attribute dimensions.

After the server extracts an attribute data set of multiple dimensions corresponding to the product information, the server may input the attribute data set of the multiple dimensions into a pre-trained sorting model, and identify the attribute data set of each dimension by using the sorting model until sorting results corresponding to the multiple dimensions are outputted according to a preset number of attribute dimensions. The pre-trained sorting model refers to a trained neural network model obtained when a neural network model is trained in advance by using a high-dimensional data sample set until the training stop condition is met. The sorting results refer to sorting results corresponding to attribute data of multiple dimensions obtained by sorting according to attributes of each dimension of the product. Specifically, the server inputs the attribute data set of the multiple dimensions corresponding to the product information into the pre-trained sorting model, and identifies the attribute data set of each dimension by using the sorting model until sorting results corresponding to the multiple dimensions are outputted according to the preset number of attribute dimensions. For example, the server inputs an attribute data set of multiple dimensions corresponding to different types of vehicle information into the pre-trained sorting model, and identifies the attribute data set of each dimension of the vehicles by using the sorting model until sorting results corresponding to the multiple dimensions of different types of vehicles are outputted according to a preset number of attribute dimensions.

In this embodiment, when there is a need to perform effective visualization difference evaluation on information of multiple dimensions included in different categories of products, the server acquires product information, extracts an attribute data set of multiple dimensions corresponding to the product information, and inputs the attribute data set of the multiple dimensions into a pre-trained sorting model, and the server identifies the attribute data set of each dimension by using the sorting model until sorting results corresponding to the multiple dimensions are outputted according to a preset number of attribute dimensions. Compared with the conventional product information processing manners, a pre-trained neural network model based on reinforcement learning can quickly and effectively process data with different data volumes, dimension numbers, and category quantities, and ensure that outputted sorting results of multiple dimensions can provide users with a product multi-dimensional information visual structure difference from an intuitive global perspective, which solves the problem of visualization processing on multi-dimensional data included in different types of product information. Even when big data includes a large amount of multi-dimensional data, the multi-dimensional information outputted after sorting can also be ensured to bring a better sorting effect, so that the users can more intuitively distinguish features of different categories of data.

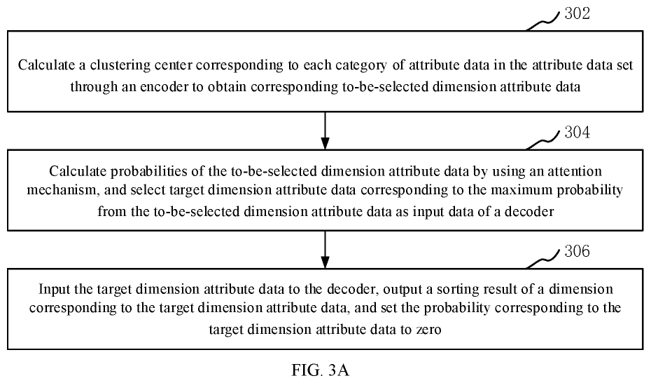

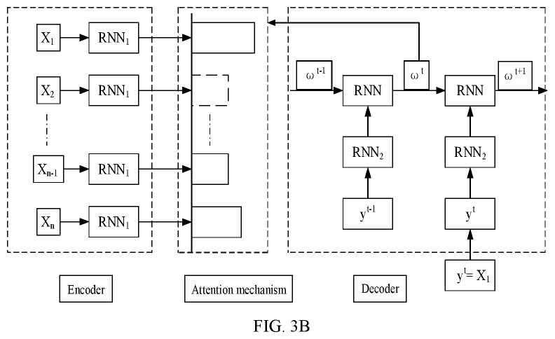

In one embodiment, as shown in FIG. 3A, a step of identifying an attribute data set of each dimension by using a sorting model includes the following steps.

In step 302, a clustering center corresponding to each category of attribute data in the attribute data set is calculated through an encoder to obtain corresponding to-be-selected dimension attribute data.

In step 304, probabilities of the to-be-selected dimension attribute data are calculated by using an attention mechanism, and target dimension attribute data corresponding to the maximum probability is selected from the to-be-selected dimension attribute data as input data of a decoder.

In step 306, the target dimension attribute data is inputted to the decoder, a sorting result of a dimension corresponding to the target dimension attribute data is outputted, and the probability corresponding to the target dimension attribute data is set to zero.

After the server inputs the attribute data set of the multiple dimensions corresponding to the product information into the pre-trained sorting model, the server identifies the attribute data set of each dimension by using the sorting model until the sorting results corresponding to the multiple dimensions are outputted according to the preset number of attribute dimensions. Specifically, refer to FIG. 3B which is a schematic diagram of a network structure of the sorting model according to one or more embodiments. RNN, RNN₁, and RNN₂ all represent recurrent neural networks. X₁ to Xₙ represent inputted data of n dimensions. X₁ denotes target dimension data corresponding to the maximum probability screened through the attention mechanism. y^{t}=X₁ denotes an optimal dimension y^{t} corresponding to current step time t outputted by the decoder according to the target dimension X₁. ω^{t} denotes feature data calculated by the RNN at the current step time t. ω^{t+1} denotes feature data calculated by the RNN at next step time t+1. ω^{t-1} denotes feature data calculated by the RNN at previous step time t−1. y^{t-1} denotes an optimal dimension y^{t-1} corresponding to the previous step time t−1 outputted by the decoder according to a previous target dimension. The decoder calculates an optimal dimension y^{t+1} corresponding to the next step time t+1 according to inputted data in the current step. The cyclic process is repeated until a sequence corresponding to the n dimensions is obtained. In an example shown in FIG. 3B, data x₁ of the first dimension is selected as output. Once y^{t} is selected, it means that a coordinate axis corresponding to x₁ is no longer a valid option. Through a masking mechanism, a log probability of an invalid state option is set to negative infinity. The sorting model uses y^{t} as input data of the decoder to calculate the optimal dimension y^{t+1} at the next step t+1. The process is repeated until a sequence of n coordinate axes is obtained. The sorting model is based on an encoder-decoder architecture, in which the encoder uses the recurrent neural networks to encode inputted multi-dimensional data points and category label information. The decoder is also formed by recurrent neural networks. The decoder takes dimension attribute data corresponding to a maximum probability currently selected through the attention mechanism as input data for calculation, and outputs a sorting result corresponding to next dimension. The server sets the probability corresponding to the target dimension attribute data to zero through the decoder, in order to exclude outputted dimension attribute data and calculate the remaining unsorted dimensions in next cyclic calculation process. The encoder and the decoder jointly determine a sequence {y^{t}}_{t=1 . . . n} of a set of optimal coordinate axes. When n-dimensional data is inputted, the sorting model may be repeatedly executed n times. Each time one of the dimension subscripts is outputted, a length of data finally outputted is also n.

Specifically, after the server inputs the attribute data set of the multiple dimensions corresponding to the product information into the pre-trained sorting model, the server calculates a clustering center corresponding to each category of attribute data in the attribute data set through an encoder to obtain corresponding to-be-selected dimension attribute data. Further, the server calculates probabilities of the to-be-selected dimension attribute data by using an attention mechanism, and selects target dimension attribute data corresponding to the maximum probability from the to-be-selected dimension attribute data as input data of a decoder. The server inputs the target dimension attribute data to the decoder, outputs a sorting result of a dimension corresponding to the target dimension attribute data, and sets the probability corresponding to the target dimension attribute data to zero. For example, after the server inputs an attribute data set of multiple dimensions corresponding to vehicle information into the pre-trained sorting model, the server calculates a clustering center corresponding to attribute data of each dimension in an attribute data set of different types of vehicles through the encoder to obtain corresponding to-be-selected dimension attribute data. For example, the first dimension X₁ is attribute data of a power performance dimension, the second dimension X₂ is attribute data of a fuel economy dimension, the third dimension X₃ is attribute data of a braking performance dimension, and so on. Further, the server calculates a probability of each piece of the to-be-selected dimension attribute data by using an attention mechanism, and selects target dimension attribute data corresponding to the maximum probability from the to-be-selected dimension attribute data, that is, selects data of the power performance dimension as the target dimension attribute data. The server takes the data of the power performance dimension as the input data of the decoder. The server inputs the data of the power performance dimension to the decoder, outputs a sorting result corresponding to the power performance dimension, and sets the probability corresponding to the power performance dimension to zero. The above steps are cyclically performed until the sorting result of each dimension corresponding to the different types of vehicles is outputted.

In this embodiment, a recurrent neural network sorting model is cyclically executed n times, data of one dimension is outputted each time, the dimension data outputted each time is selected from non-outputted data, a probability of each piece of the to-be-selected dimension data is calculated through the attention mechanism, and the dimension data with the maximum probability is selected as output, so that an obtained dimension sequence has a better visualization effect after n cycles.

In one embodiment, the step of calculating probabilities of the to-be-selected dimension attribute data by using an attention mechanism, and selecting target dimension attribute data corresponding to the maximum probability from the to-be-selected dimension attribute data as input data of a decoder includes:

calculating a valid probability graph corresponding to the attribute data set of the multiple dimensions by using the attention mechanism; ordinates of the probability graph being configured to represent probabilities, and abscissas of the probability graph being configured to represent dimensions; and

selecting target dimension attribute data corresponding to the ordinate with the maximum probability in the probability graph as the input data of the decoder.

After the server calculates the clustering center corresponding to each category of attribute data in the attribute data set through the encoder to obtain the corresponding to-be-selected dimension attribute data, the server calculates probabilities of the to-be-selected dimension attribute data by using the attention mechanism, and selects target dimension attribute data corresponding to the maximum probability from the to-be-selected dimension attribute data as input data of the decoder. Specifically, refer to FIG. 3B which is a schematic diagram of a network structure of the sorting model according to one or more embodiments. The server calculates a valid probability graph corresponding to the attribute data set of the multiple dimensions by using the attention mechanism. Ordinates of the probability graph are configured to represent probabilities, and abscissas of the probability graph are configured to represent dimensions. The server selects target dimension attribute data corresponding to the ordinate with the maximum probability in the probability graph as the input data of the decoder. For example, when the inputted data is a set {pᵢ} of m n-dimensional data points, input of an encoder module is expressed as X={xᵢ}, where xᵢ=[pᵢ, cᵢ]∈ R^{m×2}, representing values of i^{th} coordinate axes of m data points {pᵢ} and category information Cᵢ corresponding to the data points, respective clustering centers of data of K categories on an n-dimensional space are calculated through the encoder, each data point corresponds to the clustering center of the category to which it belongs, so as to obtain a matrix C ∈ R^{m×n}, and Cᵢ is data in an i^{th} column of the matrix C. The decoder takes dimension data y^{t-1} selected through the attention mechanism as input, and calculates next coordinate axis on this basis. For each step t, the attention mechanism is configured to accumulate the information calculated up to step t−1, and a probability graph of all valid dimensions is outputted. The dimension with the maximum probability may be selected as output y^{t}. The valid probability graph is valid probability values for which the probabilities are not zero. By using the masking mechanism, subscript data corresponding to outputted dimensions is recorded, and log probabilities corresponding to invalid dimension options are set to negative infinity, that is, the probabilities are set to zero, which can ensure that a recurrent neural network model may not output repeated data, so as to improve efficiency of the output of the sorting results.

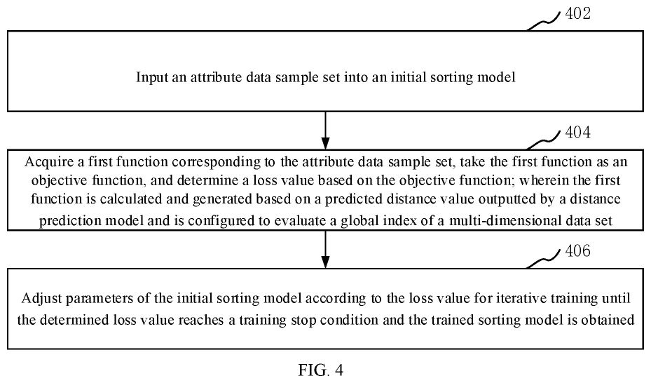

In one embodiment, as shown in FIG. 4, the step of training the sorting model includes the following steps.

In step 402, an attribute data sample set is inputted into an initial sorting model.

In step 404, a first function corresponding to the attribute data sample set is acquired, the first function is taken as an objective function, and a loss value is determined based on the objective function. The first function is calculated and generated based on a predicted distance value outputted by a distance prediction model and is configured to evaluate a global index of a multi-dimensional data set.

In step 406, the parameters of the initial sorting model are adjusted according to the loss value for iterative training until the determined loss value reaches a training stop condition and the trained sorting model is obtained.

Before the server acquires corresponding product information according to an information query instruction sent by a user, the server may train the sorting model in advance. Specifically, the server may input an attribute data sample set corresponding to the product information into an initial sorting model. The server acquires a first function corresponding to the attribute data sample set, takes the first function as an objective function, and determines a loss value based on the objective function. The first function is calculated and generated based on a predicted distance value outputted by a distance prediction model and is configured to evaluate a global index of a multi-dimensional data set. The server adjusts the parameters of the initial sorting model according to the loss value for iterative training until the determined loss value reaches a training stop condition and the trained sorting model is obtained. For example, the server may input an attribute data sample set corresponding to the product information into the initial sorting model. The attribute data sample set may be a set of attribute data of multiple dimensions, for example, a star plot sample set. In the field of information visualization, a star plot serves as a visualization method of high-dimensional data, and each coordinate axis of the star plot corresponds to data of one dimension. Therefore, the server can train the sorting model by using the star plot sample set. Specifically, the server may input a star plot sample set including attribute data of multiple dimensions into the initial sorting model. The server acquires a first function corresponding to the star plot sample set, takes the first function as an objective function, and determines a loss value based on the objective function. The first function may be a silhouette coefficient function, which is defined as a maximum value in average silhouette values of all star plot shapes of each category. A calculation formula is as follows:

SC=maxₖ₌₁^{K}Ŝₖ (1)

where SC denotes a silhouette coefficient; K denotes a total category number; and Ŝₖ denotes an average silhouette value of shapes of a category k.

For a set of shapes with different category labels, a silhouette value Sᵢ is defined to measure similarities between the shape Sᵢ and other shapes of the category to which the shape belongs and between the shape and shapes of other categories. A calculation formula of the silhouette value Sᵢ is as follows:

$${s}_{i} = \frac{{b}_{i} - {a}_{i}}{max \{ {a}_{i} , {b}_{i} \}} \qquad ( 2 )$$

where aᵢ denotes an average distance between the shape Sᵢ and other shapes of a same category; bᵢ denotes a minimum distance between the shape Sᵢ and all shapes in different categories. A calculation formula is as follows:

$${a}_{i} = \frac{1}{\vert {C}_{i} \vert - 1} {\sum }_{j \neq i , j ∈ {C}_{i}} d ( {S}_{i} , {S}_{j} ) \qquad ( 3 )$$

$${b}_{i} = {min}_{k \neq i} \frac{1}{\vert {C}_{k} \vert} {\sum }_{j ∈ {C}_{k}} d ( {S}_{i} , {S}_{j} ) \qquad ( 4 )$$

where Cᵢ denotes the category to which Sᵢ belongs.

The server takes a silhouette coefficient function as an objective function and determines a loss value based on the objective function. The silhouette coefficient function is calculated and generated according to a predicted distance value outputted by the distance prediction model, which is configured to evaluate a global index of a star plot set. Further, the server adjusts parameters of the initial sorting model according to the determined loss value for iterative training until the determined loss value reaches a training stop condition and the trained sorting model is obtained. In order to train a sorting network of the above coordinate axes, a gradient strategy is adopted, that is, a neural network training manner based on reinforcement learning is adopted. In order to measure a visual effect of the star plot set after coordinate axis sorting, a reward function is defined as a silhouette coefficient SC of the star plot set. That is, the greater the silhouette coefficient SC, the better the visualization effect after the sorting. The silhouette coefficient SC is calculated in combination with a pre-trained shape context distance prediction model to improve efficiency of the training of the sorting network. That is, the server takes the silhouette coefficient function as the objective function, and takes the silhouette coefficient SC of the star plot set as the loss value. When a slope corresponding to the loss value, that is, the silhouette coefficient SC, approaches zero, that is, the silhouette coefficient SC no longer changes, the training is stopped and the trained sorting model is obtained. Therefore, by taking the silhouette coefficient as an index to evaluate a sorting effect, a neural network sorting model is trained by reinforcement learning, so that the star plot set drawn after the sorting enable the users to better distinguish data in different categories, data with different data volumes, dimension numbers, and category quantities can be processed, and at the same time, a better sorting effect is brought.

In one embodiment, the attribute data set includes a star plot set, the star plot set of the multiple dimensions are inputted into the pre-trained sorting model, and the star plot set of each dimension is identified by using the sorting model until sorting results corresponding to the multiple dimensions of the star plot set are outputted according to the preset number of attribute dimensions.

Specifically, after the server uses the star plot sample set to train the sorting model in advance to obtain the trained sorting model, the server may input a star plot set including data of multiple dimensions into the pre-trained sorting model, and identify the star plot set of each dimension by using the sorting model until sorting results corresponding to the star plot set are outputted according to the preset number of attribute dimensions. Compared with the initially inputted star plot set, after the star plot set is identified by using the pre-trained sorting model, a value of an average silhouette coefficient in optimized coordinate axis sorting is higher than that in initial coordinate axis sorting. Therefore, a better sorting effect can be achieved, so that the neural network model can solve the problem of coordinate axis sorting in high-dimensional data visualization, so as to solve the problem of visualization processing on multi-dimensional data included in different types of product information. Even when big data includes a large amount of multi-dimensional data, the multi-dimensional information outputted after sorting can be ensured to bring a better sorting effect, so that the users can more intuitively distinguish features of different categories of data.

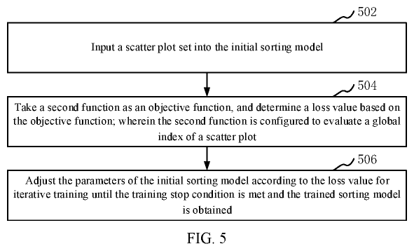

In one embodiment, as shown in FIG. 5, the step of training the sorting model includes the following steps.

In step 502, a scatter plot set is inputted into the initial sorting model.

In step 504, a second function is taken as an objective function, and a loss value is determined based on the objective function. The second function is configured to evaluate a global index of a scatter plot.

In step 506, the parameters of the initial sorting model are adjusted according to the loss value for iterative training until the training stop condition is met and the trained sorting model is obtained.

Before the server acquires corresponding product information according to an information query instruction sent by a user, the server may train the sorting model in advance. Specifically, the server may input a scatter plot set into the initial sorting model. The server may take a second function as an objective function, and determine a loss value based on the objective function. The second function is configured to evaluate a global index of a scatter plot. Further, the server adjusts the parameters of the initial sorting model according to the loss value for iterative training until the training stop condition is met and the trained sorting model is obtained. For example, in the field of information visualization, the scatter plot is also used as a visualization method of high-dimensional data. In scatter plots of high-dimensional data, radial coordinate visualization (RadViz) is a scatter plot of visualized high-dimensional data. Similar to the coordinate axis sorting problem of the star plot, the radial coordinate visualization is also required to define an evaluation index first, and then use an algorithm to optimize the sorting. Therefore, a RadViz objective function is taken as a reward function to train the network. The reward function is defined as a ratio of an original data point to a Davies-Bouldin index of a point mapped to a two-dimensional plane. The greater the value, the better the visualization effect of RadViz. Therefore, the coordinate axis sorting problem of the radial coordinate visualization can be effectively solved.

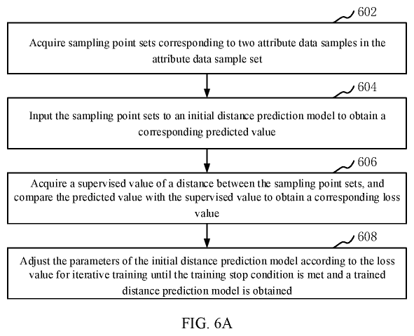

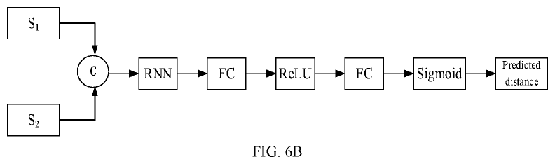

In one embodiment, as shown in FIG. 6A, the step of training the distance prediction model includes the following steps.

In step 602, sampling point sets corresponding to two attribute data samples in the attribute data sample set are acquired.

In step 604, the sampling point sets are inputted to an initial distance prediction model to obtain a corresponding predicted value.

In step 606, a supervised value of a distance between the sampling point sets is acquired, and the predicted value is compared with the supervised value to obtain a corresponding loss value.

In step 608, the parameters of the initial distance prediction model are adjusted according to the loss value for iterative training until the training stop condition is met and the trained distance prediction model is obtained.

Before the server uses the star plot sample set to train the sorting model, the server may use the sample set to first train the distance prediction model, and train the distance prediction model with a supervised learning training method. A loss function thereof is a mean square error between a predicted value and a supervised value. The supervised value is a true value. Specifically, the server may acquire sampling point sets corresponding to two attribute data samples in the attribute data sample set. The server inputs the sampling point sets corresponding to the two attribute data samples into an initial distance prediction model to obtain a corresponding predicted value. Further, the server acquires a supervised value of a distance between the sampling point sets, and compare the predicted value with the supervised value to obtain a corresponding loss value. The server adjusts the parameters of the initial distance prediction model according to the loss value for iterative training until the training stop condition is met and the trained distance prediction model is obtained. Refer to FIG. 6B which is a schematic diagram of a network structure of a shape context distance prediction model according to one or more embodiments. The distance prediction model is formed by a recurrent neural network and two fully connected layers. Finally, a predicted distance value is outputted through a Sigmoid activation layer. Inputted data are point sets obtained by sampling two shapes respectively. For example, the server may acquire two shape samples in advance and acquire 80 sampling points corresponding to each shape. The server inputs the 80 sampling points corresponding to the two shape samples into an initial distance prediction model to obtain a corresponding shape context distance predicted value. A shape context for predicting two inputted shapes describes a distance value of S1 and S2. As shown in FIG. 6B, “C” denotes a data series operation, “FC” denotes a fully connected layer, RNN denotes a recurrent neural network, ReLU denotes an activation function, and Sigmoid denotes an activation function. Therefore, a shape context distance is estimated through a pre-trained neural network model, and the predicted shape context distance is outputted, which prevents repetition of a large amount of calculation in the conventional manner, thereby effectively improving calculation efficiency.

It is to be understood that, although the steps in the flowcharts of FIG. 1 to FIG. 6 are displayed in sequence as indicated by the arrows, the steps are not necessarily performed in the order indicated by the arrows. Unless otherwise clearly specified herein, the steps are performed without any strict sequence limitation, and may be performed in other orders. In addition, at least some steps in FIG. 1 to FIG. 6 may include a plurality of steps or a plurality of stages, and such steps or stages are not necessarily performed at a same moment, and may be performed at different moments. The steps or stages are not necessarily performed in sequence, and may be performed with other steps or at least part of steps or stages in the other steps in turn or alternately.

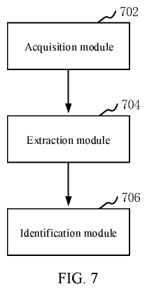

In one embodiment, as shown in FIG. 7, a product information visualization processing apparatus is provided, including: an acquisition module, an extraction module, and an identification module.

The acquisition module 702 is configured to acquire product information.

The extraction module 704 is configured to extract an attribute data set of multiple dimensions corresponding to the product information.

The identification module 706 is configured to input the attribute data set of the multiple dimensions into a pre-trained sorting model, and identify the attribute data set of each dimension by using the sorting model until sorting results corresponding to the multiple dimensions are outputted according to a preset number of attribute dimensions.

In one embodiment, the apparatus further includes: a calculation module, a selection module, and an input module.

The calculation module is configured to calculate a clustering center corresponding to each category of attribute data in the attribute data set through an encoder to obtain corresponding to-be-selected dimension attribute data. The selection module is configured to calculate probabilities of the to-be-selected dimension attribute data by using an attention mechanism, and select target dimension attribute data corresponding to the maximum probability from the to-be-selected dimension attribute data as input data of a decoder. The input module is configured to input the target dimension attribute data to the decoder, output a sorting result of a dimension corresponding to the target dimension attribute data, and set the probability corresponding to the target dimension attribute data to zero.

In one embodiment, the calculation module is further configured to calculate a valid probability graph corresponding to the attribute data set of the multiple dimensions by using the attention mechanism. The selection module is further configured to select target dimension attribute data corresponding to the ordinate with the maximum probability in the probability graph as the input data of the decoder.

In one embodiment, the apparatus further includes: a training module.

The input module is further configured to input an attribute data sample set into an initial sorting model. The selection module is further configured to acquire a first function corresponding to the attribute data sample set, take the first function as an objective function, and determine a loss value based on the objective function. The first function is calculated and generated based on a predicted distance value outputted by a distance prediction model and is configured to evaluate a global index of a multi-dimensional data set. The training module is configured to adjust the parameters of the initial sorting model according to the loss value for iterative training until the determined loss value reaches a training stop condition and the trained sorting model is obtained.

In one embodiment, the identification module is further configured to input a star plot set of the multiple dimensions into the pre-trained sorting model, and identify the star plot set of each dimension by using the sorting model until sorting results corresponding to the multiple dimensions of the star plot set are outputted according to the preset number of attribute dimensions.

In one embodiment, the apparatus further includes: a determination module.

The input module is further configured to input a scatter plot set into the initial sorting model. The determination module is further configured to take a second function as an objective function, and determine a loss value based on the objective function. The second function is configured to evaluate a global index of a scatter plot. The training module is further configured to adjust the parameters of the initial sorting model according to the loss value for iterative training until the training stop condition is met and the trained sorting model is obtained.

In one embodiment, the apparatus further includes: a comparison module.

The acquisition module is further configured to acquire sampling point sets corresponding to two attribute data samples in the attribute data sample set. The input module is configured to input the sampling point sets to an initial distance prediction model to obtain a corresponding predicted value. The comparison module is configured to acquire a supervised value of a distance between the sampling point sets, and compare the predicted value with the supervised value to obtain a corresponding loss value The training module is further configured to adjust the parameters of the initial distance prediction model according to the loss value for iterative training until the training stop condition is met and a trained distance prediction model is obtained.

Specific limitations on the product information visualization processing apparatus may be obtained with reference to the limitations on the product information visualization processing method hereinabove. Details are not described herein again. The modules in the product information visualization processing apparatus may be implemented entirely or partially by software, hardware, or a combination thereof. The above modules may be built in or independent of a processor of a computer device in a hardware form, or may be stored in a memory of the computer device in a software form, so that the processor invokes and performs operations corresponding to the above modules.

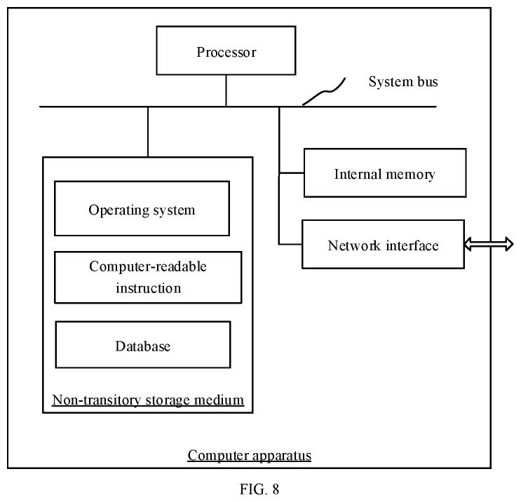

In one embodiment, a computer device is provided. The computer device may be a server. A diagram of an internal structure thereof is as shown in FIG. 8. The computer device includes a processor, a memory, and a network interface that are connected by using a system bus. The processor of the computer device is configured to provide computing and control capabilities. The memory of the computer device includes a non-transitory storage medium and an internal memory. The non-transitory storage medium stores an operating system, a computer program, and a database. The internal memory provides an environment for running of the operating system and the computer program in the non-transitory storage medium. The database of the computer device is configured to store product information visualization processing data. The network interface of the computer device is configured to communicate with an external terminal over a network. The computer program is executed by the processor to implement a product information visualization processing method.

Those skilled in the art may understand that, in the structure shown in FIG. 8, only a block diagram of a partial structure related to the solution of the present disclosure is shown, which does not constitute a limitation on the computer device to which the solution of the present disclosure is applied. Specifically, the computer device may include more or fewer components than those shown in the figure, or some components may be combined, or a different component deployment may be used.

A computer device is provided, including a memory and one or more processors, the memory storing computer-readable instructions. One or more non-transitory storage media storing computer-readable instructions are provided, the computer-readable instructions, when executed by one or more processors, causing the one or more processors to implement steps of the product information visualization processing method according to any embodiments of the present disclosure.

Those of ordinary skill in the art may understand that some or all procedures in the methods in the foregoing embodiments may be implemented by computer-readable instructions instructing related hardware, the computer-readable instructions may be stored in a non-transitory computer-readable storage medium, and when the computer-readable instructions are executed, the procedures in the foregoing method embodiments may be implemented. Any reference to the memory, storage, database, or other media used in the embodiments provided in the present disclosure may include at least one of a non-transitory memory and a transitory memory. The non-transitory memory may include a Read-Only Memory (ROM), a magnetic tape, a floppy disk, a flash memory, an optical memory, or the like. The transitory memory may include a Random Access Memory (RAM) or an external cache memory. By way of illustration instead of limitation, the RAM is available in a variety of forms, such as a Static Random Access Memory (SRAM), a Dynamic Random Access Memory (DRAM), or the like.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the invention. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

What is claimed is:

1. A product information visualization processing method, comprising:
acquiring product information; extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions,

2. The method according to claim 1, wherein the identifying the attribute data set of each dimension by using the sorting model comprises:
calculating a clustering center corresponding to each category of attribute data in the attribute data set through an encoder to obtain corresponding to-be-selected dimension attribute data; calculating probabilities of the to-be-selected dimension attribute data by using an attention mechanism, and selecting target dimension attribute data corresponding to the maximum probability from the to-be-selected dimension attribute data as input data of a decoder; and inputting the target dimension attribute data to the decoder, outputting a sorting result of a dimension corresponding to the target dimension attribute data, and setting the probability corresponding to the target dimension attribute data to zero.

3. The method according to claim 2, wherein the calculating probabilities of the to-be-selected dimension attribute data by using an attention mechanism, and selecting target dimension attribute data corresponding to the maximum probability from the to-be-selected dimension attribute data as input data of a decoder comprises:
calculating a valid probability graph corresponding to the attribute data set of the multiple dimensions by using the attention mechanism; ordinates of the probability graph being configured to represent probabilities, and abscissas of the probability graph being configured to represent dimensions; and selecting target dimension attribute data corresponding to the ordinate with the maximum probability in the probability graph as the input data of the decoder.

4. The method according to claim 1, wherein a manner of training the sorting model comprises:
inputting an attribute data sample set into an initial sorting model; acquiring a first function corresponding to the attribute data sample set, taking the first function as an objective function, and determining a loss value based on the objective function; wherein the first function is calculated and generated based on a predicted distance value outputted by a distance prediction model and is configured to evaluate a global index of a multi-dimensional data set; and adjusting parameters of the initial sorting model according to the loss value for iterative training until the determined loss value reaches a training stop condition and the trained sorting model is obtained.

5. The method according to claim 1, wherein the attribute data set comprises a star plot set; and
the star plot set of the multiple dimensions is inputted into the pre-trained sorting model, and the star plot set of each dimension is identified by using the sorting model until sorting results corresponding to the multiple dimensions of the star plot set are outputted according to the preset number of attribute dimensions.

6. The method according to claim 4, wherein the attribute data sample set comprises a scatter plot set;
the scatter plot set is inputted into the initial sorting model; a second function is taken as an objective function, and a loss value is determined based on the objective function; wherein the second function is configured to evaluate a global index of a scatter plot; and
the parameters of the initial sorting model are adjusted according to the loss value for iterative training until the training stop condition is met and the trained sorting model is obtained.

7. The method according to claim 4, wherein a manner of training the distance prediction model comprises:
acquiring sampling point sets corresponding to two attribute data samples in the attribute data sample set; inputting the sampling point sets into an initial distance prediction model to obtain a corresponding predicted value; acquiring a supervised value off distance between the sampling point sets, and comparing the predicted value with the supervised value to obtain a corresponding loss value; and adjusting the parameters of the initial distance prediction model according to the loss value for iterative training until the training stop condition is met and a trained distance prediction model is obtained.

8. (canceled)

9. A computer device, comprising a memory and one or more processors, the memory storing computer-readable instructions, the computer-readable instructions, when executed by the one or more processors, causing the one or more processors to perform the following steps:
acquiring product information; extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions,

10. The computer device according to claim 9, wherein the processor, when executing the computer-readable instructions, further performs the following steps:
calculating a clustering center corresponding to each category of attribute data in the attribute data set through an encoder to obtain corresponding to-be-selected dimension attribute data; calculating probabilities of the to-be-selected dimension attribute data by using an attention mechanism, and selecting target dimension attribute data corresponding to the maximum probability from the to-be-selected dimension attribute data as input data of a decoder; and inputting the target dimension attribute data into the decoder, outputting a sorting result of a dimension corresponding to the target dimension attribute data, and setting the probability corresponding to the target dimension attribute data to zero.

11. The computer device according to claim 10, wherein the processor, when executing the computer-readable instructions, further performs the following steps:
calculating a valid probability graph corresponding to the attribute data set of the multiple dimensions by using the attention mechanism; ordinates of the probability graph being configured to represent probabilities, and abscissas of the probability graph being configured to represent dimensions; and
selecting target dimension attribute data corresponding to the ordinate with the maximum probability in the probability graph as the input data of the decoder.

12. The computer device according to claim 9, wherein the processor, when executing the computer-readable instructions, further performs the following steps:
inputting an attribute data sample set into an initial sorting model; acquiring a first function corresponding to the attribute data sample set, taking the first function as an objective function, and determining a loss value based on the objective function; wherein the first function is calculated and generated based on a predicted distance value outputted by a distance prediction model and is configured to evaluate a global index of a multi-dimensional data set; and adjusting parameters of the initial sorting model according to the loss value for iterative training until the determined loss value reaches a training stop condition and the trained sorting model is obtained.

13. The computer device according to claim 9, wherein the processor, when executing the computer-readable instructions, further performs the following step:
inputting a star plot set of the multiple dimensions into the pre-trained sorting model, and identifying the star plot set of each dimension by using the sorting model until sorting results corresponding to the multiple dimensions of the star plot set are outputted according to the preset number of attribute dimensions.

14. The computer device according to claim 12, wherein the processor, when executing the computer-readable instructions, further performs the following steps:
inputting a scatter plot set into the initial sorting model; taking a second function as an objective function, and determining a loss value based on the objective function; wherein the second function is configured to evaluate a global index of a scatter plot; and
adjusting the parameters of the initial sorting model according to the loss value for iterative training until the training stop condition is met and the trained sorting model is obtained.

15. The computer device according to claim 12, wherein the processor, when executing the computer-readable instructions, further performs the following steps:
acquiring sampling point sets corresponding to two attribute data samples in the attribute data sample set; inputting the sampling point sets into an initial distance prediction model to obtain a corresponding predicted value; acquiring a supervised value of a distance between the sampling point sets, and comparing the predicted value with the supervised value to obtain a corresponding loss value; and adjusting the parameters of the initial distance prediction model according to the loss value for iterative training until the training stop condition is met and a trained distance prediction model is obtained.

16. One or more computer storage media storing computer-readable instructions, the computer-readable instructions, when executed by one or more processors, causing the one or more processors to perform the following steps:
acquiring product information; extracting an attribute data set of multiple dimensions corresponding to the product information; and inputting the attribute data set of the multiple dimensions into a pre-trained sorting model, and identifying the attribute data set of each dimension by using the sorting model until sorting results corresponding to the multiple dimensions are outputted according to a preset number of attribute dimensions.

17. The storage media according to claim 16, wherein the computer-readable instructions, when executed by the one or more processors, further performs the following steps:
calculating a clustering center corresponding to each category of attribute data in the attribute data set through an encoder to obtain corresponding to-be-selected dimension attribute data; calculating probabilities of the to-be-selected dimension attribute data by using an attention mechanism, and selecting target dimension attribute data corresponding to the maximum probability from the to-he-selected dimension attribute data as input data of a decoder; and inputting the target dimension attribute data to the decoder, outputting a sorting result of a dimension corresponding to the target dimension attribute data, and setting the probability corresponding to the target dimension attribute data to zero.

18. The storage media according to claim 16, wherein the computer-readable instructions, when executed by the one or more processors, further performs the following steps:
inputting an attribute data sample set into an initial sorting model; acquiring a first function corresponding to the attribute data sample set, taking the first function as an objective function, and determining a loss value based on the objective function; wherein the first function is calculated and generated based on a predicted distance value outputted by a distance prediction model and is configured to evaluate a global index of a multi-dimensional data set; and adjusting parameters of the initial sorting model according to the loss value for iterative training until the determined loss value reaches a training stop condition and the trained sorting model is obtained.

19. The storage media according to claim 18, wherein the computer-readable instructions, when executed by the one or more processors, further performs the following steps:
inputting a scatter plot set into the initial sorting model; taking a second function as an objective function, and determining a loss value based on the objective function; wherein the second function is configured to evaluate a global index of a scatter plot; and
adjusting the parameters of the initial sorting model according to the loss value for iterative training until the training stop condition is met and the trained sorting model is obtained.

20. The storage media according to claim 18, wherein the computer-readable instructions, when executed by the one or more processors, further performs the following steps: acquiring sampling point sets corresponding to two attribute data samples in the attribute data sample set; inputting the sampling point sets to an initial distance prediction model to obtain a corresponding predicted value; acquiring a supervised value of a distance between the sampling point sets, and comparing the predicted value with the supervised value to obtain a corresponding loss value; and adjusting the parameters of the initial distance prediction model according to the loss value for iterative training until the training stop condition is met and a trained distance prediction model is obtained.
